(19) United States
(12) Patent Application Publication
(10) Pub. No.: US 2011/0133562 A1
(43) Pub. Date: Jun. 9, 2011

(54) LEVEL SHIFTER

(75) Inventor: Yasuhiro Koashi, Kanagawa-ken (JP)

(73) Assignee: Kabushiki Kaisha Toshiba, Tokyo (JP)

(21) Appl. No.: 12/956,454

(22) Filed: Nov. 30, 2010

(30) Foreign Application Priority Data
Dec. 3, 2009 (JP) 2009-275393

(51) Int. Cl. H03L 5/00

(52) U.S. Cl. 307/80

(57) ABSTRACT

According to one embodiment, a level shifter includes a transmission circuit and a controller. The transmission circuit is connected between a first circuit operating at a first power source voltage and a second circuit operating at a second power source voltage higher than the first power source voltage. The transmission circuit includes a first switch element receiving a signal input to one terminal and outputting the signal to another terminal. The first or second power source voltage is supplied to the another terminal of the first switch element via a resistance element and the controller supplies the another terminal of the first switch element with a current in an identical direction to a current flowing from the resistance element when the first switch element is switched to an OFF state.

### CROSS-REFERENCE TO RELATED APPLICATIONS

This application is based upon and claims the benefit of priority from the prior Japanese Patent Application No. 2009-275393, filed on Dec. 3, 2009; the entire contents of which are incorporated herein by reference.

### FIELD

Embodiments described herein relate generally to a level shifter.

### BACKGROUND

Voltage reductions of integrated circuits such as CPUs have been progressing with the need to reduce the power consumption and increase the functions of devices. On the other hand, there are cases where high voltages are necessary in existing systems and systems handling analog signals and the like.

Thus, in the case where coexisting systems operate at different power source voltages, level shifters are necessary to transmit signals between the systems.

There are applications in which bus switch ICs including CMOS logic are used to convert signal voltage levels to connect systems having different power source voltages. For example, in the case where a level shift of a signal is performed from a low level voltage to a high level voltage, the level shift is performed utilizing the OFF characteristics of the switch element using a pull-up resistor. However, because the signal transfer after the switch element is switched OFF is a signal transfer having a CR time constant determined by the pull-up resistor and the load capacitance, the speed of the signal transfer decreases.

In a system having a bi-directional input-output (capable of a input and a output) terminal, there are cases where a control is performed by the signal level input when the input-output terminal is switched from output to input. It has been proposed to increase the speed of the control by detecting the signal level of such an input-output terminal, e.g., the RESET terminal of a microcontroller (for example, refer to U.S. Pat. No. 5,894,240).

However, when a system detects only the signal level on the side of the circuit controlled by the CR time constant, there are limitations on the high-speed transmission of signals between circuits operating at different power source voltages.

### BRIEF DESCRIPTION OF THE DRAWINGS

FIG. 1 is a circuit diagram illustrating the configuration of a level shifter according to an embodiment;

FIGS. 2A to 2E are timing charts of the main signals of the controller of the level shifter;

FIG. 3 is a schematic view illustrating the temporal change of the potentials of the input signal VA and the output signal VB;

FIG. 4 is a circuit diagram illustrating another configuration of the level shifter according to this embodiment;

FIG. 5 is a circuit diagram illustrating the configuration of the internal level shifter illustrated in FIG. 4; and

FIG. 6 is a circuit diagram illustrating another configuration of the level shifter according to this embodiment.

### DETAILED DESCRIPTION

In general, according to one embodiment, a level shifter includes a transmission circuit and a controller. The transmission circuit is connected between a first circuit operating at a first power source voltage and a second circuit operating at a second power source voltage higher than the first power source voltage. The transmission circuit includes a first switch element receiving a signal input to one terminal and outputting the signal to another terminal. The first or second power source voltage is supplied to the another terminal of the first switch element via a resistance element and the controller supplies the another terminal of the first switch element with a current in an identical direction to a current flowing from the resistance element when the first switch element is switched to an OFF state.

Embodiments will now be described in detail with reference to the drawings.

In the specification and the drawings of the application, components similar to those described in regard to a drawing thereinabove are marked with like reference numerals, and a detailed description is omitted as appropriate.

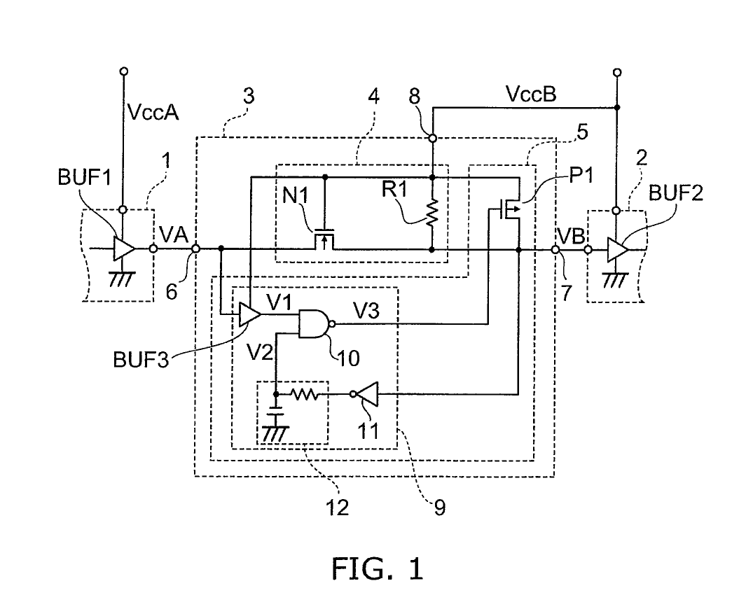

FIG. 1 is a circuit diagram illustrating the configuration of a level shifter according to an embodiment.

FIG. 1 illustrates a first circuit 1, a second circuit 2, and a level shifter 3.

The first circuit 1 includes a buffer BUF1 and the like and is a circuit operating at a first power source voltage VCCA. The first circuit 1 outputs a signal (an input signal) VA having a low level of the grounding potential and a high level of the first power source voltage VCCA. As the first circuit 1, FIG. 1 illustrates only the buffer BUF1 that outputs the signal (the input signal) VA.

The second circuit 2 includes a buffer BUF2 and the like and is a circuit operating at a second power source voltage VCCB. The second circuit 2 receives input of a signal (an output signal) VB having a low level of the grounding potential and a high level of the second power source voltage VCCB. As the second circuit 2, FIG. 1 illustrates only the buffer BUF2 that receives input of the signal (the output signal) VB.

The first power source voltage VCCA is, for example, 1.5 to 3.3 V; and the second power source voltage VCCB is, for example, 2.3 to 5.5 V. However, the second power source voltage VCCB is higher than the first power source voltage VCCA.

The level shifter 3 includes a transmission circuit 4, a controller 5, a first terminal 6, a second terminal 7, and a power source terminal 8. A structure may be provided in which these components are formed on the same semiconductor substrate in one chip; or a structure may be provided in which these components are formed in multiple chips.

The level shifter 3 performs a level shift of a signal input to the first terminal 6 and outputs to the second terminal 7. In other words, the input signal VA is input from the first circuit 1; and a level-shifted output signal VB is output to the second circuit 2. The second power source voltage VCCB is supplied to the power source terminal 8.

The transmission circuit 4 includes a first switch element N1 and a first resistor (a resistance element) R1.

The first switch element N1 is an N-channel MOSFET (hereinbelow, NMOS). The first switch element N1 is connected between the first terminal 6 and the second terminal 7. In other words, the first switch element N1 is connected between the first circuit 1 operating at the first power source voltage VCCA and the second circuit 2 operating at the second power source voltage VCCB which is higher than the first power source voltage VCCA.

The input signal VA from the first circuit 1 is input to one terminal of the first switch element N1. The level-shifted output signal VB is output to one other terminal of the first switch element N1. Further, the output signal VB is input to the second circuit 2. The second power source voltage VCCB is supplied to the gate of the first switch element N1.

The first resistor (the resistance element) R1 is connected between the second terminal 7 and the power source terminal 8 and supplies the second power source voltage VCCB to the one other terminal, i.e., the output side, of the first switch element N1. Although the first resistor (the resistance element) R1 is provided in the transmission circuit 4 in the level shifter 3 illustrated in FIG. 1, the first resistor (the resistance element) R1 may be provided in the second circuit 2. Also, the first resistor (the resistance element) R1 may be driven by the buffer BUF1 of the first circuit 1; and it is sufficient that the first resistor (the resistance element) R1 is capable of limiting the current flowing in the case where voltages are applied to both ends

The transmission circuit 4 transmits the input signal VA input from the first circuit 1 operating at the first power source voltage VCCA to the second circuit 2 operating at the second power source voltage VCCB as the level-shifted output signal VB.

The controller 5 includes an OFF detector 9 and a second switch element P1.

The input signal VA and the output signal VB of the first switch element N1 are input to the OFF detector 9. The output of the OFF detector 9 is input to the second switch element P1 to control the second switch element P1.

The OFF detector 9 includes a circuit of an inversion of AND (a NAND) 10, an inversion circuit (an INV) 11, a delay circuit 12, and a buffer BUF3.

The input of the buffer BUF3 is connected to the first terminal 6; and an output V1 of the buffer BUF3 is input to the NAND 10. The input of the INV 11 is connected to the second terminal 7; and the output of the INV 11 is input to the delay circuit 12. An output V2 of the delay circuit 12 is input to the NAND 10.

In other words, the input signal VA of the first switch element N1 is input to the NAND 10 via the buffer BUF3. The output signal VB of the first switch element N1 is inverted via the INV 11, is delayed by the delay circuit 12, and is input to the NAND 10.

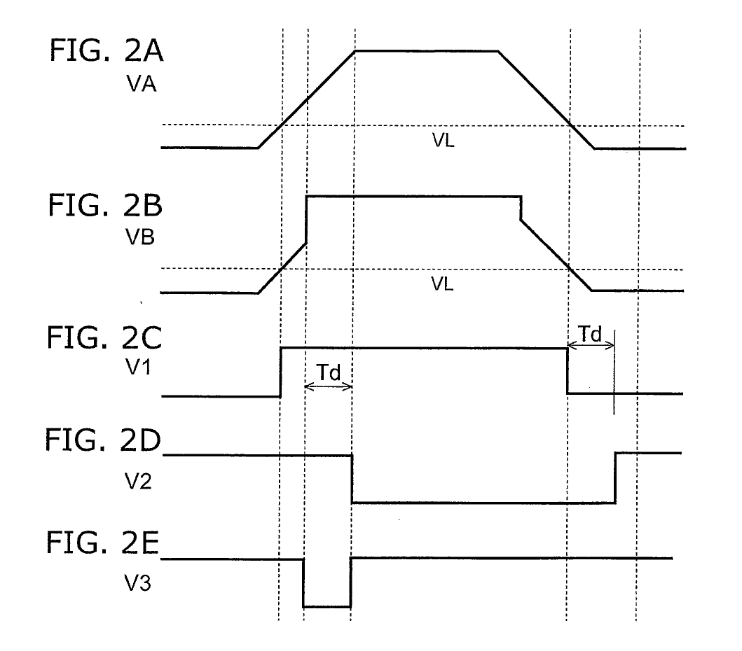

The delay circuit 12 is a circuit that outputs the input signal after a delay of a delay time Td. As illustrated in FIG. 1, the delay circuit 12 may include a resistor and a capacitor. In such a case, the delay time Td is determined by the time constant of the resistor and the capacitor. The delay circuit 12 may include, for example, an even number of INVs having cascade connections. The delay time Td is described using FIGS. 2A to 2E.

An output V3 of the NAND 10 is input to the gate of the second switch element P1 to control the second switch element P1. In other words, the input signal VA and the output signal VB of the first switch element N1 are input to the OFF detector 9; and the second switch element P1 is controlled by the output V3 of the OFF detector 9.

The second switch element P1 is a P-channel MOSFET (hereinbelow, PMOS). The second switch element P1 is connected between the second terminal 7 and the power source terminal 8.

The second switch element P1 is controlled by the output V3 of the OFF detector 9 and supplies the second power source voltage VCCB to the one other terminal, i.e., the output side, of the first switch element N1 when the first switch element N1 is in the OFF state as described below.

The controller 5 operates at the second power source voltage VCCB supplied from the power source terminal 8.

Operations of the level shifter 3 will now be described.

FIGS. 2A to 2E are timing charts of the main signals of the controller of the level shifter. FIG. 2A illustrates the input signal VA; FIG. 2B illustrates the output signal VB; and FIGS. 2C to 2E illustrate the signals (the outputs) V1 to V3 of the controller, respectively.

As illustrated in FIG. 2A, the potential of the input signal VA ramp-ups from the low level to the high level. At this time, the first switch element N1 is in the ON state; and the potential of the output signal VB follows the input signal VA to ramp-up from the low level to the high level (FIG. 2B).

When the potential of the input signal VA exceeds a logic threshold voltage VL of the buffer BUF3, the potential of the output V1 of the buffer BUF3 changes from the low level to the high level (FIG. 2C). When the potential of the output signal VB exceeds the logic threshold voltage VL of the INV 11, the output of the INV 11 inverts from the high level to the low level. Then, the potential of the output V2 of the delay circuit 12 changes from the high level to the low level after a delay of the delay time Td of the delay circuit 12 (FIG. 2D).

The potential of the output V3 of the NAND 10 changes from the high level to the low level after a delay of the propagation delay time from the output V1 to the NAND 10. Further, the potential of the output V3 of the NAND 10 returns again to the high level after the delay time Td of the delay circuit 12 elapses. In other words, a negative pulse having a duration of the delay time Td is formed (FIG. 2E).

In the case where the output V3 of the NAND 10, i.e., the output V3 of the OFF detector 9, is the low level, the second switch element P1 is switched to the ON state. Therefore, the second terminal 7 is in the state of being electrically connected to the power source terminal 8; and the second power source voltage VCCB is supplied to the one other terminal (the output side) of the first switch element N1. In other words, in the case where the first switch element N1 is switched to the OFF state, the second power source voltage VCCB is supplied to the one other terminal (the output side) of the first switch element N1 via the second switch element P1. Current is supplied to the one other terminal (the output side) of the first switch element N1; and the potential of the output signal VB increases at a high rate.

In the case where the first switch element N1 is in the OFF state, the transmission circuit 4 cannot transmit the input signal VA as the output signal VB. Therefore, the first circuit 1 and the second circuit 2 are switched to a cut off state when the potentials of the input signal VA and the output signal VB of the first switch element N1 increase and the first switch element N1 is switched to the OFF state.

The potential of the output signal VB increases due to the second power source voltage VCCB supplied via the first resistor (the resistance element) R1. In other words, current is supplied via the first resistor (the resistance element) R1; and the potential of the output signal VB increases. Here, in the case where the second switch element P1 is not provided, the change of the potential of the output signal VB is limited by the time constant of the first resistor (the resistance element) R1 and the electrostatic capacitance of the input of the second circuit 2.

In the level shifter 3 according to this embodiment, in the case where the first switch element Ni is switched to the OFF state, the second power source voltage VCCB is supplied via the second switch element P1 of the controller 5. Current is supplied via the second switch element P1 to the one other terminal (the output side) of the first switch element N1 in the same direction as the current flowing from the first resistor (the resistance element) R1. Thereby, the increase of the potential of the output signal VB accelerates to change with the time constant of the ON resistance of the second switch element P1 and the electrostatic capacitance of the input of the second circuit 2.

Thus, a high-speed signal transmission is possible according to the level shifter 3.

In the level shifter 3 illustrated in FIG. 1, the current is supplied to the one other terminal (the output side) of the first switch element N1 by supplying the second power source voltage VCCB via the second switch element P1. However, when the potential of the output V3 of the OFF detector 9 is the low level, a current generator that supplies current to the one other terminal (the output side) of the first switch element N1 may be used.

During the OFF state of the first switch element N1 in the case where the potential of the input signal VA decreases (FIG. 2A), the potential of the output signal VB remains at the high level (FIG. 2B).

When the potential of the input signal VA decreases and the first switch element N1 is switched to the ON state, the potential of the output signal VB decreases at a high rate and follows the potential of the input signal VA.

When the potential of the input signal VA decreases below the logic threshold voltage VL, the potential of the output V1 of the buffer BUF3 changes to the low level (FIG. 2C). When the potential of the output signal VB decreases below the logic threshold voltage VL, the potential of the output V2 of the delay circuit 12 changes to the high level after the delay time Td (FIG. 2D). The potential of the output V3 of the NAND 10 remains at the high level (FIG. 2E).

Thus, the potential of the output V3 of the NAND 10 remains at the high level when the potentials of the input signal VA and the output signal VB ramp-down from the high level to the low level.

However, in the case where the potential of the input signal VA switches to the high level while the potential of the output V2 of the delay circuit 12 is at the high level, the output V3 of the OFF detector 9 switches to the low level and a misoperation occurs. Such a misoperation can be avoided by setting the delay time Td of the delay circuit 12 longer than the time of the trailing edge of the potentials of the input signal VA and the output signal VB.

Thus, the OFF detector 9 operates as an edge detector that detects the rising edge of the potentials of the input signal VA and the output signal VB. The case where the first switch element N1 switches from the ON state to the OFF state is detected by detecting the rising edge of the potentials of the input signal VA and the output signal VB.

Then, as recited above, in the case where the first switch element N1 is switched to the OFF state, the controller 5 supplies current to the one other terminal (the output side) of the first switch element N1 by supplying the second power source voltage VCCB. In other words, the OFF detector 9 detects the first switch element N1 switching from the ON state to the OFF state; the second switch element P1 is switched to the ON state; and the second power source voltage VCCB is supplied to the one other terminal (the output side) of the first switch element N1. The current is supplied to the one other terminal (the output side) of the first switch element N1 in the same direction as the current flowing from the first resistor (the resistance element) R1.

The temporal change of the potentials of the input signal VA and the output signal VB will now be described based on the operations of the level shifter 3 recited above.

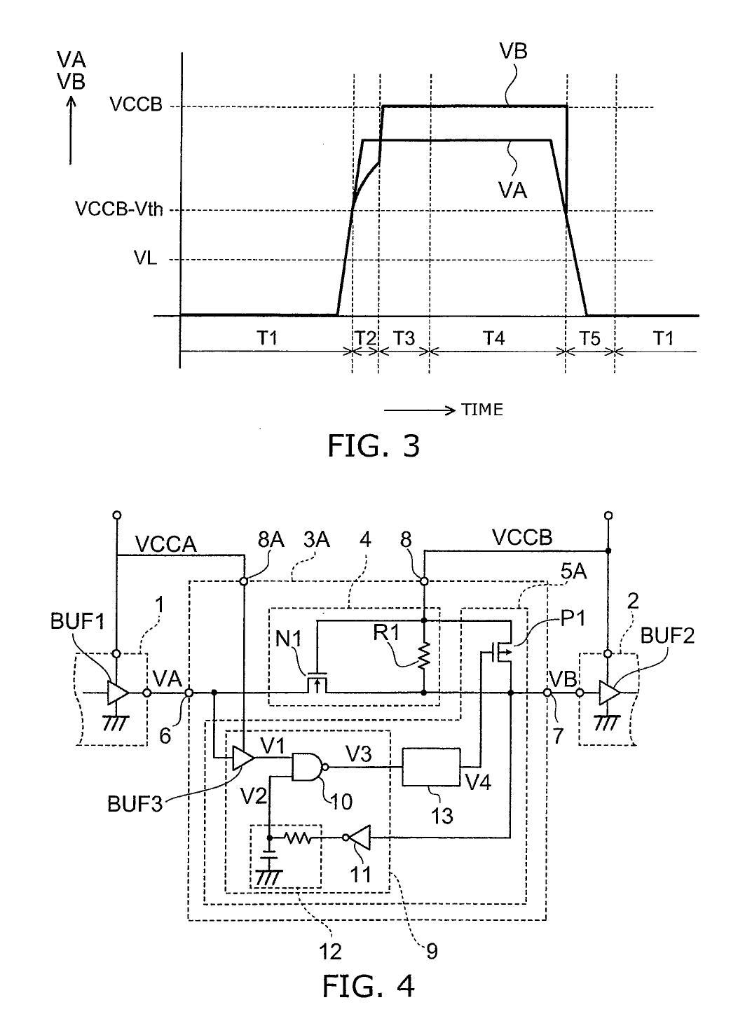

FIG. 3 is a schematic view illustrating the temporal change of the potentials of the input signal VA and the output signal VB.

FIG. 3 schematically illustrates the potential of the input signal VA and the potential of the output signal VB plotted on the vertical axis and the time plotted on the horizontal axis. The temporal change of the potential of the output signal VB is illustrated for the case where the potential of the input signal VA changes from the low level to the high level and again returns to the low level.

As illustrated in FIG. 3, the temporal change of the potentials of the input signal VA and the output signal VB are divided into five intervals of an interval T1 to an interval T5 based on the operations of the level shifter 3.

The interval T1 is the case where the potential of the input signal VA is low and the transmission circuit 4 is in the ON state, i.e., the case where the first switch element N1 is in the ON state.

The second power source voltage VCCB is supplied to the gate of the first switch element N1. Therefore, the first switch element N1 is in the ON state in the case where the potential of the input signal VA is not more than VCCB-Vth, where Vth is the threshold voltage of the first switch element N1. The potential of the output signal VB increases by following the potential of the input signal VA.

When the potential of the input signal VA exceeds VCCB-Vth, the first switch element N1 is switched to the OFF state. In this state, the input signal VA input from the first circuit 1 cannot be transmitted as the output signal VB to the second circuit 2.

An interval T2 is an interval after the first switch element N1 is switched to the OFF state during which the output V3 of the OFF detector 9 remains at the high level. The second power source voltage VCCB is supplied to the one other terminal (the output side) of the first switch element N1 via the first resistor (the resistance element) R1. The potential of the output signal VB increases with a time constant of the first resistor (the resistance element) R1 and the electrostatic capacitance between the second terminal 7 and the ground. In the case where the load capacitance of the second terminal 7, i.e., the electrostatic capacitance of the input of the second circuit 2, is large, the potential of the output signal VB is limited by the time constant of the first resistor (the resistance element) R1 and the electrostatic capacitance of the input of the second circuit 2 and is delayed.

An interval T3 is the case where the potential of the output V3 of the OFF detector 9 is the low level, i.e., the case where the second switch element P1 is in the ON state. The second power source voltage VCCB is supplied to the one other terminal (the output side) of the first switch element N1 via the second switch element P1. The potential of the output signal VB is accelerated to increase with a time constant of the ON resistance of the second switch element P1 and the electrostatic capacitance of the input of the second circuit 2. Because the ON resistance of the second switch element P1 is lower than the resistance value of the first resistor (the resistance element) R1, the potential of the output signal VB increases at a high rate. Therefore, applications are possible even in the case where the load capacitance is large and in the case where the input signal VA changes at a high rate.

An interval T4 is the interval during which the potential of the output V3 of the OFF detector 9 returns to the high level. The potential of the output V3 of the OFF detector 9 returns to the high level after the delay time Td of the delay circuit 12 elapses from being switched to the low level. The second switch element P1 returns to the OFF state.

In the case where the potential of the output signal VB is maintained at the high level during the interval T4, the first and second switch elements N1 and P1 are in the OFF states in a state of low current consumption.

In the case where the potential of the input signal VA changes from the high level to the low level, the first switch element N1 is in the OFF state until the potential of the input signal VA decreases below VCCB-Vth. The potential of the output signal VB remains at the high level.

The interval T5 is the interval during which the potential of the input signal VA decreases and the first switch element N1 returns to the ON state and is the interval until the potential of the output V2 of the delay circuit 12 returns to the high level. The first switch element N1 returns to the ON state when the potential of the input signal VA decreases below VCCB-Vth. The potential of the output signal VB decreases by following the input signal VA.

When the potential of the output signal VB decreases to the low level, the potential of the output V2 of the delay circuit 12 is switched to the high level after the delay time Td elapses. As recited above, the potential of the output V3 of the OFF detector 9 is switched to the low level and a misoperation occurs in the case where the potential of the input signal VA is switched to the high level during the delay time Td. Therefore, the delay time Td is set to a time to avoid such misoperations by being set longer than the time of the trailing edge of the potentials of the input signal VA and the output signal VB.

After the interval T5 elapses, the state returns to the interval T1. The first switch element N1 is in the ON state and the second switch element P1 is in the OFF state.

The potential of the output signal VB follows the potential of the input signal VA and is the low level.

Thus, in the controller 5 of the level shifter 3, the OFF state of the first switch element N1 is detected by inputting the input signal VA and the output signal VB to the OFF detector 9. The ON state of the second switch element P1 is controlled by the output V3 of the OFF detector 9 to supply the second power source voltage VCCB to the one other terminal (the output side) of the first switch element N1. In other words, the controller 5 supplies current to the one other terminal (the output side) of the first switch element N1 in the same direction as the current flowing from the first resistor (the resistance element) R1.

In the case where the first switch element N1 is in the OFF state as recited above, the input signal VA input from the first circuit 1 is not transmitted as the output signal VB to the second circuit 2. The increase of the potential of the output signal VB is limited by the time constant of the first resistor (the resistance element) R1 and the electrostatic capacitance of the input of the second circuit 2. Therefore, the change of the potential of the output signal VB is slower than that of the potential of the input signal VA. Accordingly, the detection of the OFF state of the first switch element N1 is delayed in the case where the change of the first switch element N1 from the ON state to the OFF state is detected by detecting only the potential of the output signal VB. Then, the control of switching the second switch element P1 to the ON state also is delayed.

Conversely, in the OFF detector 9, the OFF state of the first switch element N1 can be detected more quickly because the input signal VA is input with the output signal VB.

According to the level shifter 3 according to this embodiment, the controller 5 supplies current to the one other terminal (the output side) of the first switch element N1 in the same direction as the current flowing from the first resistor (the resistance element) R1 in the case where the input signal VA and the output signal VB increase and the transmission circuit 4 is switched to the OFF state. Thereby, the increase of the potential of the output signal VB can be accelerated and the speed of the transmission of the signal between the input and the output, i.e., from the first circuit 1 to the second circuit 2, can be increased.

The OFF detector 9 illustrated in FIG. 1 detects the OFF of the first switch element N1 by detecting the rising edge of the potentials of the input signal VA and the output signal VB. However, the OFF detector of the first switch element N1 may have a configuration that detects using a comparator of the potentials of the input signal VA and the output signal VB and the like.

During the interval T2 as recited above, the first and second switch elements N1 and P1 are in the OFF states and the change of the potential of the output signal VB is in a slow state controlled by the first resistor (the resistance element) R1.

The interval T2 changes with the logic threshold voltage VL of the buffer BUF3 included in the OFF detector 9 and the propagation delay time of the buffer BUF3, the NAND 10, etc.

Therefore, the change occurs with the power source voltage supplied to the OFF detector 9. For example, reducing the power source voltage reduces the logic threshold voltage VL; and the detection of the OFF state of the first switch element N1 can be faster.

FIG. 4 is a circuit diagram illustrating another configuration of the level shifter according to this embodiment.

As illustrated in FIG. 4, a level shifter 3A includes the transmission circuit 4, a controller 5A, the first and second terminals 6 and 7, the power source terminal 8, and a low potential power source terminal 8A.

The controller 5A includes the second switch element P1, the OFF detector 9, and an internal level shifter 13. In other words, the level shifter 3A has a configuration in which the controller 5 of the level shifter 3 illustrated in FIG. 1 is replaced with the controller 5A and the low potential power source terminal 8A is added. The first power source voltage VCCA is supplied to the low potential power source terminal 8A.

The controller 5A differs from the controller 5 illustrated in FIG. 1 in that the internal level shifter 13 is added and the first power source voltage VCCA is supplied to the OFF detector 9 via the low potential power source terminal 8A. The configurations of the transmission circuit 4, the second switch element P1, the first and second terminals 6 and 7, the power source terminal 8, and the OFF detector 9 are similar to those of FIG. 1.

In the controller 5A as illustrated in FIG. 4, the logic threshold voltage VL of the buffer BUF3 can be reduced by supplying the first power source voltage VCCA to the OFF detector 9. Thereby, as described in regard to FIG. 3, the potential of the output V1 of the buffer BUF3 changes quickly to the high level; and the interval T2 can be shortened. Then, the input signal VA input from the first circuit 1 can be transmitted at a high speed as the output signal VB to the second circuit 2.

However, because the high level of the potential of the output V3 of the OFF detector 9 is the first power source voltage VCCA, the potential of the high level is converted to the second power source voltage VCCB by the internal level shifter 13.

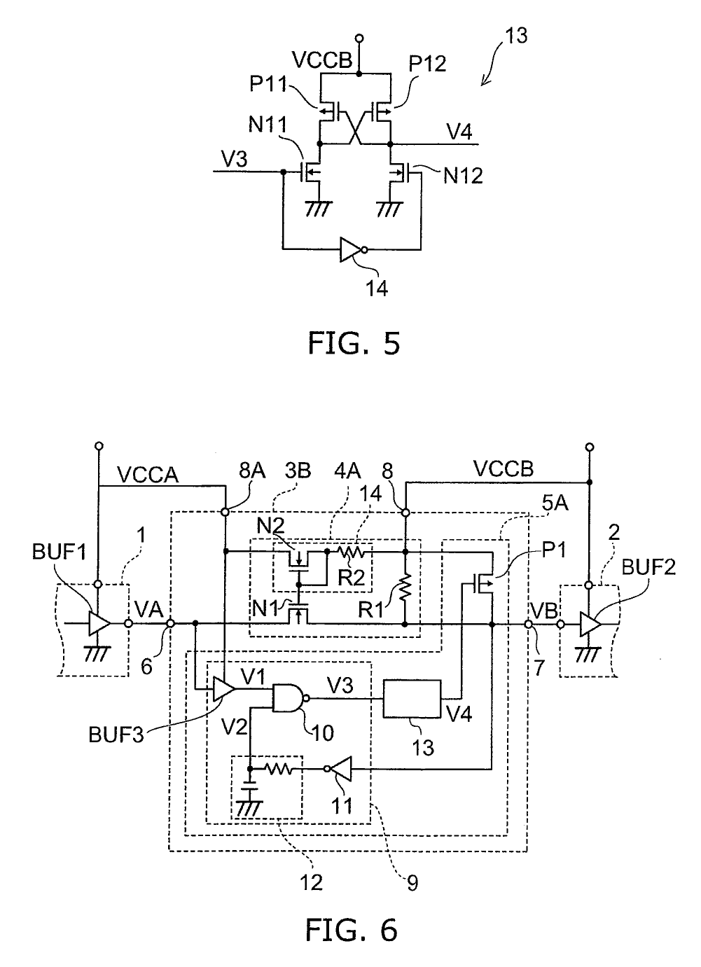

FIG. 5 is a circuit diagram illustrating the configuration of the internal level shifter illustrated in FIG. 4.

As illustrated in FIG. 5, the internal level shifter 13 includes NMOSs N11 and N12, PMOSs P11 and P12, and an INV 14.

The sources of each of the NMOSs N11 and N12 are connected to the ground. The output V3 of the OFF detector 9 is input to the gate of the NMOS N11. The output V3 of the OFF detector 9 is input to the gate of the NMOS N12 via the INV 14.

The drains of the NMOSs N11 and N12 are connected to the drains of the PMOSs P11 and P12, respectively. The second power source voltage VCCB is supplied to the source of each of the PMOSs P11 and P12. The gate of the PMOS P11 is connected to the drain of the PMOS P12; and these are used as an output V4 of the internal level shifter 13. The gate of the PMOS P12 is connected to the drain of the PMOS P11.

The output V3 of the OFF detector 9 having a high level of the first power source voltage VCCA and a low level of 0 V is input to the internal level shifter 13.

For example, in the case where the high level (VCCA) is input as the output V3, the potential of the drain of the NMOS N11 is the low level (0 V); and the potential of the drain of the NMOS N12, i.e., the output V4, is the high level (VCCB). In other words, the output amplitude of the internal level shifter 13 is 0 V to VCCB.

The internal level shifter 13 performs a voltage conversion from the input of the output V3 of the OFF detector 9, which has a high level of the first power source voltage VCCA and a low level of 0 V, to the output V4, which has a high level of the second power source voltage VCCB and a low level of 0 V.

The gate of the second switch element P1 is controlled by the output V4.

Other than the decrease of the logic threshold voltage VL, the operations of the OFF detector 9 illustrated in FIG. 4 are similar to those of the timing charts of FIGS. 2A to 2E. Further, the temporal change of the potentials of the input signal VA and the output signal VB of the level shifter 3A illustrated in FIG. 4 is similar to that of the schematic view of FIG. 3.

Accordingly, according to the level shifter 3A, a level shifter capable of a high-speed signal transmission can be provided.

However, as illustrated in FIG. 1 and FIG. 4, the second power source voltage VCCB is supplied to the gate of the first switch element N1. In such a case, the potential of the input signal VA that switches the first switch element N1 to the OFF state is VCCB-Vth.

The first power source voltage VCCA may be supplied to the gate of the first switch element Ni. In such a case, the potential of the input signal VA that switches the first switch element N1 to the OFF state is VCCA-Vth.

The potential of the input signal VA that switches the first switch element N1 to the OFF state changes due to the gate potential of the first switch element N1.

FIG. 6 is a circuit diagram illustrating another configuration of the level shifter according to this embodiment.

As illustrated in FIG. 6, the level shifter 3B includes a transmission circuit 4A, the controller 5A, the first and second terminals 6 and 7, the power source terminal 8, and the low potential power source terminal 8A.

The transmission circuit 4A includes the first switch element N1, the first resistor (the resistance element) R1, and a bias circuit 15. In other words, the transmission circuit 4A has a configuration in which the bias circuit 15 is added to the transmission circuit 4 illustrated in FIG. 1.

The first switch element N1, the first resistor (the resistance element) R1, the controller 5A, the first and second terminals 6 and 7, the power source terminal 8, and the low potential power source terminal 8A are similar to those of the level shifter 3A illustrated in FIG. 4.

The bias circuit 15 includes an NMOS (a first transistor) N2 and a second resistor R2 connected in series to the NMOS N2. The source of the NMOS N2 is connected to the low potential power source terminal 8A and is supplied with the first power source voltage VCCA. The gate and the drain of the

NMOS N2 are connected to the power source terminal 8 via the second resistor R2 and are supplied with the second power source voltage VCCB. The NMOS N2 has a diode-like connection.

The gate (the control terminal) of the first switch element N1 is connected to the gate of the NMOS N2.

Accordingly, a bias voltage of VCCA +Vth2 is supplied to the gate of the first switch element N1 by the bias circuit 15. In the case where the threshold voltage Vth2 of the NMOS N2 is equal to the threshold voltage Vth of the first switch element N1, the potential of the input signal VA that switches the first switch element N1 to the OFF state is substantially the first power source voltage VCCA.

Thus, the potential of the input signal VA that switches the first switch element N1 to the OFF state can be changed by supplying the bias voltage to the gate of the first switch element N1.

Accordingly, the interval T2, from when the first switch element N1 is switched to the OFF state to when the potential of the output V3 of the OFF detector 9 becomes the low level and the second switch element P1 is switched to the ON state, can be adjusted to be shortened.

Accordingly, according to the level shifter 3B, a level shifter capable of a high-speed signal transmission can be provided.

The potential of the input signal VA that switches the first switch element N1 to the OFF state is changed by supplying the bias voltage to the gate of the first switch element N1. Therefore, the range of the potentials that can undergo a level shift between the input and the output can be changed. In other words, the degrees of freedom of the voltages can be increased.

In the level shifters 3, 3A, and 3B hereinabove, the case is described where the input signal VA input from the first circuit 1 is output as the output signal VB to the second circuit 2. However, it is also possible for the level shifter according to this embodiment to output an input signal input from the second circuit 2 as an output signal to the first circuit 1. In other words, signals can be transmitted in both directions.

Further, in the case where the signal is transmitted in the direction from the second circuit 2 to the first circuit 1, it is possible to perform a high-speed signal transmission by providing the first resistor (the resistance element) R1 and the second switch element P1 on the output side, i.e., on the first circuit 1 side.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A level shifter, comprising:
a transmission circuit connected between a first circuit operating at a first power source voltage and a second circuit operating at a second power source voltage higher than the first power source voltage, the transmission circuit including a first switch element receiving a signal input to one terminal and outputting the signal to another terminal, the first or second power source voltage being supplied to the another terminal of the first switch element via a resistance element; and
a controller supplying the another terminal of the first switch element with a current in an identical direction to a current flowing from the resistance element when the first switch element is switched to an OFF state.

2. The shifter according to claim 1, wherein the controller detects the OFF state of the first switch element by detecting a rising edge of an output signal of the first switch element.

3. The shifter according to claim 2, wherein the controller operates at the second power source voltage.

4. The shifter according to claim 2, wherein the controller operates at the first power source voltage.

5. The shifter according to claim 1, wherein the controller includes:
an OFF detector detecting the OFF state of the first switch element by receiving inputs of an input signal and an output signal of the first switch element; and
a second switch element controlled by an output of the OFF detector to supply the first or second power source voltage to the another terminal of the first switch element.

6. The shifter according to claim 5, wherein the OFF detector includes an edge detector detecting a rising edge of the input signal and the output signal of the first switch element.

7. The shifter according to claim 6, wherein the edge detector includes a delay circuit set to a delay time longer than a time of a trailing edge of the output signal of the first switch element.

8. The shifter according to claim 6, wherein the OFF detector operates at the second power source voltage.

9. The shifter according to claim 6, wherein the OFF detector operates at the first power source voltage.

10. The shifter according to claim 1, wherein the transmission circuit further includes a bias circuit supplying a bias voltage to a control terminal of the first switch element.

11. The shifter according to claim 10, wherein the controller detects the OFF state of the first switch element by detecting a rising edge of an output signal of the first switch element.

12. The shifter according to claim 10, wherein the controller operates at the second power source voltage.

13. The shifter according to claim 10, wherein the controller . operates at the first power source voltage.

14. The shifter according to claim 10, wherein the controller includes:
an OFF detector detecting the OFF state of the first switch element by receiving inputs of an input signal and an output signal of the first switch element; and
a second switch element controlled by an output of the OFF detector to supply the first or second power source voltage to the another terminal of the first switch element.

15. The shifter according to claim 10, wherein the OFF detector includes an edge detector detecting a rising edge of the input signal and the output signal of the first switch element.

16. The shifter according to claim 15, wherein the edge detector includes a delay circuit set to a delay time longer than a time of a trailing edge of the output signal of the first switch element.

17. The shifter according to claim 14, wherein the OFF detector operates at the second power source voltage.

18. The shifter according to claim 14, wherein the OFF detector operates at the first power source voltage.

19. The shifter according to claim 10, wherein the bias circuit includes:
a first transistor having a diode-like connection; and
a second resistor connected in series with the first transistor.

20. The shifter according to claim 19, wherein the controller detects the OFF state of the first switch element by detecting a rising edge of an output signal of the first switch element.
